(19) United States
(12) Patent Application Publication
(10) Pub. No.: US 2025/0083416 A1
(43) Pub. Date: Mar. 13, 2025

(54) TRANSPARENT SUBSTRATE PROVIDED WITH A FUNCTIONAL STACK OF THIN LAYERS

(71) Applicant: SAINT-GOBAIN GLASS FRANCE, COURBEVOIE (FR)

(72) Inventors: Denis GUIMARD, AUBERVILLIERS (FR); Romain HIVET, AUBERVILLIERS (FR)

(21) Appl. No.: 18/729,809

(22) PCT Filed: Jan. 25, 2023
(86) PCT No.: PCT/EP2023/051828

§ 371 Date: Jul. 17, 2024

(30) Foreign Application Priority Data
Jan. 27, 2022 (FR) 2200706
Apr. 28, 2022 (FR) 2203983
Jan. 5, 2023 (WO) PCT/EP2023/050188

(51) Int. Cl. B32B 17/10; C03C 17/34

(52) U.S. Cl. CPC B32B 17/10201; B32B 17/10036; C03C 17/3435; B32B 2255/20; B32B 2255/28; B32B 2307/204; C03C 2217/219; C03C 2218/156

(57) ABSTRACT

A transparent substrate provided on one of its main surfaces with a stack of thin layers, the stack of layers including the following layers starting from the substrate: a first dielectric module of one or more thin layers; a tungsten oxide absorbing layer; a second dielectric module of one or more thin layers; wherein the tungsten oxide includes at least one doping element selected from chemical elements of group 1 according to IUPAC nomenclature.

### TECHNICAL FIELD

The invention to a transparent substrate provided with a stack of thin layers conferring “solar control” properties.

### TECHNICAL BACKGROUND

Functional stacks of thin layers are commonly used to provide functions of thermal insulation and/or solar protection to glazings equipping buildings. They aim in particular to reduce the air-conditioning effort and/or to reduce excessive overheating (so-called “solar control” glazings) and/or to reduce the amount of energy dissipated to the outside (so-called “low-emission” glazings).

Solar control functions are desired for the glazings capable of being exposed to high sunshine levels. The capacity of a glazing to limit the amount of light energy transmitted is defined by the solar factor, g, which is the ratio of the total energy transmitted through the glazed surface or the interior glazing to the incident solar energy. The lower the solar factor, g value, the better the protection against solar radiation.

It is common to use “solar control” glazings provided with a stack of thin layers devoid of functional metal layers when radio frequency transparency properties are desired. Instead of functional metallic layers, functional layers that absorb infrared radiation are generally used. They may be based on oxides and/or nitrides.

JP 2010180449 A [SUMITOMO METAL MINING CO [JP]] Aug. 19, 2010 describes a layer based on tungsten oxide deposited by sputtering using a tungsten oxide target comprising chemical elements selected from hydrogen, alkali metals, alkaline earth metals and rare earth metals. The layer has a “solar control” function by virtue of its high absorption of near-infrared radiation.

EP 3686312 A1 [SUMITOMO METAL MINING CO [JP]] Jul. 29, 2020 describes a layer based on cesium oxide doped with cesium, and a method for depositing such a layer by sputtering. The layer has a transparency to radio waves and a “solar control” function by virtue, in particular, of its high absorption of infrared radiation.

### SUMMARY OF THE INVENTION

### Technical Problem

A functional stack is described as a functional stack suitable for building applications when it meets a double requirement: high light transmission and a low solar factor value. A functional stack is therefore suitable when it has a selectivity value, s, defined as the ratio of the light transmission to the high solar factor.

Additionally, it is preferable for a functional stack to have a certain chemical and mechanical durability for certain applications, in particular in single glazings, when it is directly exposed to the external or internal environment of a building.

There also remains a need to improve the energy performance of the stacks of thin layers that do not comprise any functional metal layers reflecting infrared radiation, in particular that do not comprise silver-based functional metal layers.

Radio frequency transparency may further be desired.

### Solution to the Technical Problem

A first aspect of the invention relates to a transparent substrate as described in claim 1, the dependent claims being advantageous embodiments.

The transparent substrate according to the invention is provided on one of its main surfaces with a stack of thin layers, said stack of layers consisting of the following layers starting from the substrate:
a first dielectric module of one or more thin layers;
an absorbent tungsten oxide layer;
a second dielectric module of one or more thin layers;
   wherein the tungsten oxide comprises at least one doping element selected from the chemical elements of group 1 according to the IUPAC nomenclature

Other advantageous embodiments are presented in the detailed description.

A second aspect of the invention relates to a glazing comprising a transparent substrate according to the first aspect of the invention.

A third aspect of the invention relates to a method for manufacturing a transparent substrate according to the first aspect of the invention.

### Advantages of the Invention

A notable advantage of a glazing comprising a transparent substrate according to the invention is a gain of up to more than 10% on the selectivity while maintaining a sufficient light transmission level, greater than 65% in single glazing applications, and a thermal transmission factor, Ug, of 5 W/m²·K, or even less.

Another advantage of the invention is that the functional stack has better mechanical and chemical durability, as well as preservation of its optical and energy performance after heat treatment, in particular by the encapsulation of the tungsten oxide layer by nitride-based layers, as detailed in some embodiments.

### BRIEF DESCRIPTION OF THE DRAWINGS

FIG. 1 is a schematic depiction of a first embodiment of the first aspect of the invention.

FIG. 2 is a schematic depiction of a first embodiment of a double glazing according to the second aspect of the invention.

FIG. 3 is a schematic depiction of a second embodiment of a double glazing according to the second aspect of the invention.

FIG. 4 is a schematic depiction of a laminated glazing according to the second aspect of the invention.

FIG. 5 is a schematic depiction of the light transmission and of the solar factor for several examples of glazing according to the invention and three counter-examples.

FIG. 6 is a schematic depiction of the light reflection on the interior face and the exterior face for several examples of glazing according to the invention and three counter-examples.

FIG. 7 is a schematic depiction of the color parameters a* and b* in transmission, in internal reflection and in external reflection for several examples of glazing according to the invention and three counter-examples.

FIG. 8 is a schematic depiction of the light transmission and of the solar factor for several examples of laminated glazing according to the invention and three counter-examples.

FIG. 9 is a schematic depiction of the light reflection on the interior face and the exterior face for several examples of laminated glazing according to the invention and three counter-examples.

FIG. 10 is a schematic depiction of the color parameters a* and b* in transmission, in internal reflection and in external reflection for several examples of laminated glazing according to the invention and three counter-examples.

### DETAILED DESCRIPTION OF EMBODIMENTS

The following definitions and conventions are used.

The term “above”, respectively “below”, describing the position of a layer or of an assembly of layers and defined in relation to the position of another layer or another assembly, means that said layer or said assembly of layers is closer to, respectively further from, the substrate.

These two terms, “above” and “below”, do not at all mean that the layer or the assembly of layers which they describe and the other layer or the other assembly with respect to which they are defined are in contact. They do not exclude the presence of other intermediate layers between these two layers. The expression “in contact” is explicitly used to indicate that no other layer is positioned between them.

Without any fuller information or qualifier, the term “thickness” used for a layer corresponds to the physical, real or geometric thickness, e, of said layer. It is expressed in nanometers.

The expression “dielectric module” denotes one or more layers in contact with one another forming an assembly of layers which is dielectric overall, that is to say that it does not have the functions of a functional metal layer. If the dielectric module comprises several layers, they may themselves be dielectric. The physical, real or geometric thickness, of a dielectric module of layers, corresponds to the sum of the physical, real or geometric thicknesses, of each of the layers which constitute it.

In the present description, the expressions “a layer of” or “a layer based on”, used to describe a material or a layer as to what it contains, are used equivalently. They mean that the mass fraction of the constituent that it comprises is at least 50%, in particular at least 70%, preferably at least 90%. In particular, the presence of minority or doping elements is not excluded.

The term “transparent” used to describe a substrate means that the substrate is preferably colorless, non-opaque and non-translucent in order to minimize the absorption of the light and thus retain a maximum light transmission in the visible electromagnetic spectrum.

“Light transmittance” is understood to mean the light transmittance, denoted TL, as defined and measured in section 4.2 of the standard EN 410.

The light transmission in the visible spectrum, TL, the solar factor, g, and the selectivity, s, the internal reflection, Rint, and the external reflection, Rext, in the visible spectrum are defined, measured and calculated in conformity with the standards EN 410, ISO 9050 and ISO 10292.

In the case of a laminated glazing, “thermal transmission factor,” Ug, is understood to mean the thermal transmission factor as defined according to standards EN 673.

In accordance with the nomenclature of IUPAC, group 1 of the chemical elements comprises hydrogen and alkaline elements, that is, lithium, sodium, potassium, rubidium, cesium and francium.

The expressions “optical refraction index” and “optical extinction coefficient”, are understood as the optical refraction index, n, and optical extinction coefficient, k, as defined in the technical field, in particular according to the Forouhi & Bloomer described in the Forouhi & Bloomer, Handbook of Optical Constants of Solids II, Palik, E. D. (ed.), Academic Press, 1991, Chapter 7.

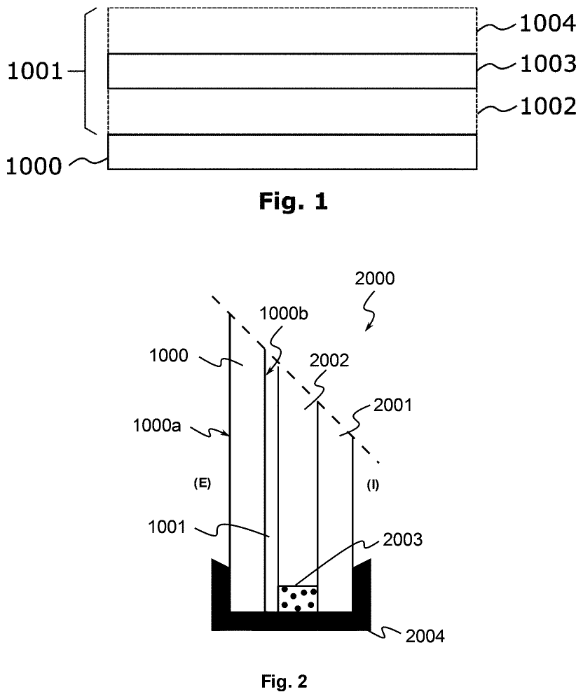

According to a first aspect of the invention, with reference to FIG. 1, a transparent substrate 1000 is provided, having on one of its main surfaces a stack 1001 of thin layers, said stack 1001 of layers consisting of the following layers starting from the substrate 1000:
a first dielectric module 1002 of one or more thin layers;
an absorbent layer 1003 of tungsten oxide;
a second dielectric module 1004 of one or more thin layers;

The tungsten oxide comprises at least one doping element selected from the chemical elements of group 1 according to the IUPAC nomenclature.

The absorbent tungsten oxide layer 1003 is a layer that absorbs infrared radiation, preferably that absorbs infrared radiation whose wavelength is greater than 780 nm.

Surprisingly, an absorbent layer 1003 of tungsten oxide comprising a doping element chosen from the elements of group 1 according to the nomenclature of the IUPAC encapsulated between two dielectric modules makes it possible to increase selectivity.

The stack 1001 of the transparent substrate 1000 according to the first aspect of the invention does not comprise any functional metallic layers.

According to certain particular embodiments, the absorbent tungsten oxide layer 1003 may comprise the doping element X or the doping elements X1, X2, . . . in proportions such that the molar ratio, X/W of said element on tungsten, W, or the sum of the molar ratios of each element on tungsten (X1+X2+ . . . )/W is between 0.01 and 1, preferably between 0.01 and 0.6, or even between 0.02 and 0.3.

It was observed that these values of molar ratio can make it possible to obtain optimal selectivity values while making it possible to limit the amount of doping elements used, and therefore to generate a saving on the exploitation of mineral resources for the doping elements, as well as a reduction in manufacturing costs.

According to certain embodiments, the absorbent layer 1003 of tungsten oxide may comprise at least one doping element selected from hydrogen, lithium, sodium, potassium and cesium.

Among the elements of group 1, these particular elements can make it possible to obtain advantageous selectivity values, that is higher values.

According to particularly preferred embodiments, the absorbent layer 1003 of tungsten oxide may comprise cesium as a doping element, and the molar ratio of cesium to tungsten is between 0.01 and 1, preferably between 0.05 and 0.4. These embodiments make it possible to obtain the best performance as to the increase in selectivity, the preservation of colors, and the cost savings.

According to certain embodiments, the thickness of the absorbent layer 1003 of tungsten oxide may be between 6 and 450 nm, preferably between 20 and 250 nm, or even between 40 and 200 nm.

The transparent substrate 1000 may preferably be planar. It may be of organic or inorganic nature, rigid or flexible. In particular, it may be a mineral glass, for example a soda-lime-silica glass.

Examples of organic substrates which can advantageously be used in the implementation of the invention may be polymer materials, such as polyethylenes, polyesters, polyacrylates, polycarbonates, polyurethanes or polyamides. These polymers can be fluoropolymers.

Examples of inorganic substrates which can advantageously be employed in the invention may be sheets of inorganic glass or glass-ceramic. The glass may preferably be a glass of soda-lime-silica, borosilicate, aluminosilicate or else alumino-borosilicate type. According to a preferred embodiment of the invention, the transparent substrate 1000 is a sheet of soda-lime-silica mineral glass.

According to certain embodiments, the first dielectric module 1002 and/or the second dielectric module 1004 may comprise one or more layers based on nitride and/or oxide, preferably based on zinc and tin oxide, zinc oxide, titanium oxide, zirconium oxide, aluminum nitride, silicon and zirconium nitride or silicon nitride optionally doped with aluminum, zirconium and/or boron.

According to advantageous embodiments, the first dielectric module 1002 and/or the second dielectric module 1004 consist of one or more nitride-based layers. According to examples of embodiments, the nitride-based layer(s) of the first dielectric module 1002 and/or the second dielectric module 1004 are chosen from aluminum nitride, silicon nitride, titanium nitride, niobium nitride, silicon zirconium nitride, silicon nitride doped with aluminum, zirconium and/or boron.

When the layer(s) of the first dielectric module 1002 and of the second dielectric mode 1004 are nitride-based, they make it possible to encapsulate the absorbent layer based on tungsten oxide.

This encapsulation allows a double protection of the absorbent layer 1003 based on tungsten oxide. On the one hand, it prevents any contamination by elements capable of diffusing into the stack 1001 from the substrate 1000, such as in particular alkali metal ions or oxygen in the case of a heavy mineral glass substrate. On the other hand, it makes it possible to limit, in particular during a heat treatment step of the annealing type, the diffusion of oxygen into the stack 1001 toward the absorbent layer 1003 based on tungsten oxide from the atmosphere and/or the substrate.

By virtue of the encapsulation, the chemical composition and the degree of oxidation of the absorbent layer 1003 of tungsten oxide vary little over time, or if they vary, this variation is favorable for the selectivity. Moreover, when the stack is subjected to an annealing heat treatment, the encapsulation ensures a proper level of selectivity. In use, the substrate 1000 according to the first aspect of the invention is more durable, in particular its performance is preserved over the long term.

A second aspect of the invention relates to a glazing, in particular a single, double or triple glazing, and a laminated glazing, comprising a transparent substrate according to the first aspect of the invention.

According to a second aspect of the invention, a single or double glazing is provided comprising a substrate according to the first aspect of the invention.

A single glazing, or monolithic glazing, comprises a single substrate, in particular a mineral glass sheet. When the substrate according to the invention is used as monolithic glazing, the functional stack of this layers is preferably deposited on the face of the substrate directed toward the interior of the room of the building on the walls of which the glazing is installed. In such a configuration, it can be advantageous to protect the first layer and optionally the stack of thin layers from physical or chemical damage using an appropriate means.

A multiple glazing comprises at least two substrates, in particular mineral glass sheets, that are parallel and separated by an insulating gas-filled cavity. The majority of multiple glazings are double or triple glazings, that is to say that they respectively comprise two or three glazings. When the substrate according to the invention is used as element of a multiple glazing, the functional stack of thin layers is preferably deposited on the face of the glass sheet directed inward in contact with the insulating gas. This arrangement has the advantage of protecting the stack from chemical or physical damage from the external environment.

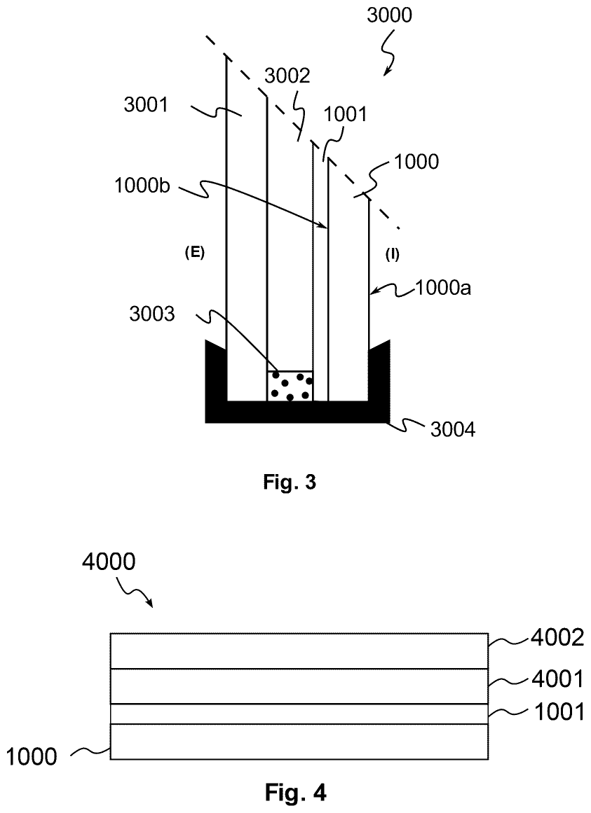

According to preferred embodiments, with reference to FIG. 2 and FIG. 3, the glazing is a double glazing 2000, 3000 comprising a transparent substrate 1000 according to any one of the above-disclosed embodiments so that the functional stack 1001 of layers is located facing two and/or three of said glazing 9000, 10000. In the figure, (E) corresponds to the exterior of the premises where the glazing is installed, and (I) to the interior of the premises.

According to a first embodiment, with reference to FIG. 2, the glazing 2000 comprises a first transparent glass sheet 1000 with an inner surface 1000a and an outer surface 1000b, a second glass sheet 2001 with an inner surface and an outer surface, an insulating gas-filled cavity 2002, a spacer 2003 and a seal 2004.

The glass sheet 1000 comprises, on and in contact with its inner surface 1000b in contact with the gas of the insulating gas-filled cavity 9002, a functional stack 1001 according to the first aspect of the invention. The functional assembly 1001 is preferably deposited so that its outer surface, which is opposite the surface 1000b of the transparent glass sheet 1000, is directed toward the interior (I) of the premises, for example a building, in which the glazing is used. In other words, the functional stack 1001 is arranged on face 2 of the glazing starting from the exterior (E).

According to another embodiment, with reference to FIG. 3, the glazing is a double glazing 3000 comprising a first glass sheet 1000 with an inner surface 1000a and an outer surface 1001b, a second transparent glass sheet 3001 with an inner surface and an outer surface, an insulating gas-filled cavity 3004, a spacer 3003 and a seal 3004.

The glass sheet 1000 comprises, on its inner surface 1000a in contact with the gas of the insulating gas-filled cavity 9004, a functional stack 1001 according to the first aspect of the invention. The functional assembly 1001 is preferably arranged so that its outer surface that is opposite the surface 1000a of the transparent glass sheet 1000 is directed toward the exterior (E) of the premises. In other words, the functional stack (1001) is arranged on face 3 of the glazing starting from the exterior (E).

Referring to FIG. 4, also provided is a laminated glazing 4000 comprising a first transparent substrate 1000 according to the first aspect of the invention, a lamination interlayer 4001 and a second transparent substrate 4002, such that the first transparent substrate 1000 and the second transparent substrate 4002 are in adhesive contact with the lamination interlayer 4001 and the stack 1001 of thin layers of the first transparent substrate 1000 is in contact with the lamination interlayer 4001.

The lamination interlayer 4001 may consist of one or more layers of thermoplastic material. Examples of thermoplastic material are polyurethane, polycarbonate, polyvinyl butyral (PVB), polymethyl methacrylate (PMMA), ethylene vinyl acetate (EA) or an ionomer resin.

The lamination interlayer 4001 may be in the form of a multilayer film. It may also have particular functionalities such as, for example, acoustic or anti-UV properties.

Typically, the lamination interlayer 4001 comprises at least one PVB layer. Its thickness is between 50 μm and 4 mm. In general, it is less than 1 mm.

The methods for depositing thin layers on substrates, in particular glass substrates, are methods well known in industry. By way of example, the deposition of a stack of thin layers on a glass substrate is carried out by successive depositions of each thin layer of said stack by passing the glass substrate through a succession of deposition cells suitable for depositing a given thin layer.

The deposition cells can use deposition methods such as magnetic field assisted sputtering, ion beam assisted deposition (IBAD), evaporation, chemical vapor deposition (CVD), plasma enhanced chemical vapor deposition (PECVD), low pressure chemical vapor deposition (LPCVD), etc.

The magnetic field enhanced sputtering deposition method is particularly used. The conditions for deposition of layers are widely documented in the literature, for example in patent applications WO2012/093238 A1 and WO2017/00602 A1.

According to a third aspect of the invention, a method is provided for manufacturing a transparent substrate according to the first aspect of the invention, wherein the absorbent layer of tungsten oxide is deposited by a magnetron sputtering method using a tungsten oxide target doped using a chemical element chosen from the chemical elements of group 1 according to the IUPAC nomenclature.

The tungsten oxide target may in particular contain one or more doping elements in the proportions as described for the tungsten oxide layer doped in some embodiments of the first aspect of the invention.

The absorbent layer of tungsten oxide can be deposited by sputtering using the aforementioned target under a deposition atmosphere composed of 60 to 100% argon and 0 to 40% dioxygen, preferably 70 to 85% argon and 15 to 30% dioxygen.

The absorbent tungsten oxide layer may be deposited under a pressure between 1 to 15 mTorr, preferably 3 to 10 m Torr.

Preferably, the deposition can be carried out cold, that is to say at a temperature of less than 100° C., in particular between 20° C. and 60° C., for the substrate.

The deposition can also be carried out hot, in particular at a temperature between 100° C. and 400° C.

According to particular embodiments, the substrate 1000, after deposition of the stack 1001, can undergo an annealing heat treatment. The annealing temperature may be between 450° C. and 800° C., in particular between 550° C. and 750° C., or even between 600° C. and 700° C. The annealing time may be between 5 min and 30 min, in particular between 5 min and 20 min, or even between 5 min and 10 min.

All the embodiments described, whether they relate to the first aspect or the second aspect of the invention, can be combined with one another without modification or particular adaptation. In the event that technical incompatibilities appear during the implementation of one of these combinations, it is within the scope of the person skilled in the art to be able to solve them by means of their knowledge without this requiring undue effort, in particular by implementing a research program.

### Examples

The features and advantages of the invention are shown by the non-limiting examples described hereinafter.

Twenty-three examples, E1-E23, in accordance with the invention are described in Tables 1, 2, 3 and 4 which indicate the composition and the thickness expressed in nanometers of the various layers. The numbers in the first column correspond to the references of the figures.

The layer, denoted CWO, of cesium-doped tungsten oxide. The molar ratio of cesium to tungsten in the layer is about 0.05-0.06.

TABLE 1

| | | E1 | E2 | E3 | E4 | E5 | E6 |
|---|---|---|---|---|---|---|---|
| 1004 | SiN | 83 | 103 | 43 | 140 | 42 | 41 |
| | TiN | | | | | | |
| | NiCr | | | | | | 1.8 |
| | NbN | | | | 0.7 | | |
| | SiN | | | | 29 | | 7 |
| 1003 | CWO | 49 | 368 | 67 | 64 | 67 | 45 |
| 1002 | SiN | | | 62 | | 58 | |
| | TiN | | | | | | |
| | NiCr | | | | | 0.4 | |
| | NbN | | | 0.5 | | | |
| | SiN | 39 | 83 | 109 | 47 | | 51 |
| 1000 | glass | 6 mm | 6 mm | 6 mm | 6 mm | 6 mm | 6 mm |

TABLE 2

| | | E7 | E8 | E9 | E10 | E11 | E12 |
|---|---|---|---|---|---|---|---|
| 1004 | SiN | 44 | 60 | 67 | 74 | 71 | 41 |
| | TiN | | 3.4 | | | | |
| | NiCr | | | | | | |
| | NbN | | | | | | |
| | SiN | | 107 | | | | |
| | SiZrN27 | | | | 44 | | 108 |
| | SiZrN17 | | | 50 | | 88 | |
| 1003 | CWO | 64 | 69 | 47 | 51 | 59 | 64 |
| 1002 | SiZrN27 | | | | 97 | | 121 |
| | SiZrN17 | | | 107 | | 128 | |
| | SiN | 69 | | | | | 7 |
| | TiN | 2.1 | | | | | |
| | NiCr | | | | | | |
| | NbN | | | | | 0.9 | 0.7 |
| | SiN | 104 | 176 | 5 | 5 | 147 | 33 |
| 1000 | glass | 6 mm | 6 mm | 6 mm | 6 mm | 6 mm | 6 mm |

TABLE 3

| | | E13 | E14 | E15 | E16 | E17 | E18 |
|---|---|---|---|---|---|---|---|
| 1004 | SiN | 118 | 104 | 45 | 18 | 28 | 27 |
| | TiN | | | | | 13.2 | 10.2 |
| | NiCr | | | | | | |
| | NbN | | | 5.2 | | | |
| | SiN | | | 17 | | 29 | 29 |
| | SiZrN27 | | | | | | |
| | SiZrN17 | | | | | | |
| 1003 | CWO | 121 | 89 | 54 | 19 | 43 | 51 |
| 1002 | SiZrN27 | | | | | | |
| | SiZrN17 | | | | | | |
| | SiN | | 27 | | 5 | | 38 |
| | TiN | | | | 18 | | 2 |
| | NiCr | | | | | | |
| | NbN | | 1.8 | | | | |
| | SiN | 89 | 56 | 41 | 16 | 60 | 11 |
| 1000 | glass | 6 mm | 6 mm | 6 mm | 6 mm | 6 mm | 6 mm |

TABLE 4

| | | E19 | E20 | E21 | E22 |
|---|---|---|---|---|---|
| 1004 | SiN | 105 | 146 | 15 | 15 |
| | TiN | | | | 21 |
| | NiCr | | | | |
| | NbN | | | 7.5 | |
| | SiN | | | 55 | 64 |
| | SiZrN27 | | | | |
| | SiZrN17 | | | | |
| 1003 | CWO | 199 | 92 | 40 | 53 |
| 1002 | SiZrN27 | | | | |
| | SiZrN17 | | | | |
| | SiN | | 103 | | |
| | TiN | | | | |
| | NiCr | | | | |
| | NbN | | 10 | | |
| | SiN | 24 | 67 | 44 | 36 |
| 1000 | glass | 6 mm | 6 mm | 6 mm | 6 mm |

Three counter-examples, CE1-CE3 are described in Table 5 which indicates the composition and thickness expressed in nanometers of the various layers.

TABLE 5

| | | CE1 | CE2 | CE3 |
|---|---|---|---|---|
| 1004 | SiN | 41 | 34 | 28 |
| | TiN | | | |
| | NiCr | | | |
| | NbN | 2.1 | 5.6 | |
| | SiN | | | |
| | SiZrN27 | | | |
| | SiZrN17 | | | |
| 1003 | CWO | | | |
| 1002 | SiZrN27 | | | |
| | SiZrN17 | | | |
| | SiN | | | |
| | TiN | | | |
| | NiCr | | | |
| | NbN | | | 10.4 |
| | SiN | 5 | 8 | 5 |
| 1000 | glass | 6 mm | 6 mm | 6 mm |

The first dielectric module 1002 and the second dielectric module 1004 of examples E1, E2, E13 and E19 comprise only silicon nitride-based layers of different thicknesses.

The first dielectric module 1002 and/or the second dielectric module 1004 of examples E3 to E6, E14 to E15 and E21 comprise, in addition to silicon nitride-based layers, a layer of niobium nitride and/or mixed nickel-chromium nitride.

The first dielectric module 1002 and/or the second dielectric module 1004 of examples E8 to E12 comprise, in addition to silicon nitride-based layers, a layer of niobium nitride and/or mixed nickel-chromium nitride.

The mixed silicon-zirconium nitride, SiZrN17, contains 17 at. % zirconium, and the mixed silicon-zirconium nitride, SiZrN27, contains 27 at. % zirconium.

The first dielectric module 1002 and/or the second dielectric module 1004 of examples E16 to E18 and E22 comprise, in addition to silicon nitride-based layers, a layer of titanium nitride.

Counter-example CE1 corresponds to examples E1 to E12, counter-example CE2 to examples E13 to E18, and counter-example CE3 to examples E19 to E23.

The stacks of thin layers of examples E1-E23 and of counter-examples CE1-CE3 were deposited by magnetic-field-assisted cathode sputtering (magnetron method) whose characteristics are widely documented in the literature, for example in patent applications WO2012/093238 and WO2017/00602. The substrate 1000 is a soda-lime-silica mineral glass 4 mm thick. After deposition, the substrates were subjected to a heat treatment at 650° C. for 10 min under air.

The nature of the targets used and the deposition conditions of examples E1 to E23 and counter-examples CE1-CE3 are grouped in table 6.

TABLE 6

| | | Pres- | | | | Pow- |
|---|---|---|---|---|---|---|
| | | sure | Ar | O2 | N2 | er |
| | Target | (μbar) | (sccm) | (sccm) | sccm) | (W) |
| SiN | Si:Al | 5 | 7 | 0 | 14 | 2000 |
| SiZr27N | Si:Zr 27 at. % | 2 | 15 | 0 | 15 | 1000 |
| SiZr17N | Si:Zr 17 at. % | 2 | 15 | 0 | 18 | 1000 |
| NbN | Nb | 2 | 40 | 0 | 10 | 500 |
| TiN | Ti | 2 | 32 | 0 | 15 | 2500 |
| NiCr | NiCr:Cr 20 wt. % | 2 | 20 | 0 | 0 | 500 |
| CWO | CWO:Cs/ | 4-10 | 30-40 | 2-10 | 0 | 1300 |
| | W 0.3-0.4 | | | | | |

The solar factor, g, the selectivity, s, the light transmission, TL, the light reflection on the interior face, Rint, and on the exterior face, Rext, as well as the color in transmission, on the interior face and on the exterior face, were measured for each substrate of examples E1 to E17 and of counter-examples CE1 to CE4 assembled in a single glazing.

The expression “color”, used to describe a transparent substrate provided with a stack, is understood to mean the color as defined in the L*a*b* CIE 1976 chromatic space according to standard ISO 11664, in particular with a D65 illuminant and a visual field of 2° or 10° for the reference observer. It is measured in accordance with said standard.

The light transmission in the visible spectrum, TL, the solar factor, g, and the selectivity, s, and the internal reflection, Rint, and the external reflection, Rext, in the visible spectrum are defined, measured and calculated in conformity with the standards EN 410, ISO 9050 and/or ISO 10292.

The thermal transmission factor, Ug, is defined, measured and calculated in accordance with standard EN 673.

Measurements of solar factor, selectivity, light transmission, internal and external reflection, and emissivity are grouped in Table 7. Measurements of color parameters a* and b*, in transmission (a*T, b*T), external reflection (a*Rext, b*Rext) and internal reflection (a*Rint, b*Rint) are grouped in Table 8.

TABLE 7

| | g | s | Tl | Rint | Rext | Ug |
|---|---|---|---|---|---|---|
| E1 | 65.5 | 1.08 | 70.5 | 11.8 | 16.6 | 5.7 |
| E2 | 54.2 | 1.29 | 70 | 12.9 | 15.2 | 5.7 |
| E3 | 61.1 | 1.15 | 70 | 9.7 | 7.2 | 5.7 |
| E4 | 59.3 | 1.13 | 67 | 7.7 | 9.3 | 5.7 |
| E5 | 61.1 | 1.15 | 70 | 9.7 | 7.3 | 5.7 |
| E6 | 64.2 | 1.09 | 70 | 8.6 | 5.5 | 5.7 |
| E7 | 60 | 1.17 | 70 | 9.3 | 6.8 | 5.7 |
| E8 | 56 | 1.2 | 67.4 | 10.9 | 7.3 | 5.7 |
| E9 | 62.6 | 1.12 | 70 | 9.8 | 12.4 | 5.7 |
| E10 | 61.8 | 1.13 | 70 | 10.4 | 10.3 | 5.7 |
| E11 | 58.5 | 1.2 | 70 | 8.8 | 8.1 | 5.7 |
| E12 | 57.2 | 1.21 | 69.1 | 9 | 8.5 | 5.7 |
| E13 | 48.5 | 1.08 | 52.2 | 12.3 | 16 | 5.7 |
| E14 | 50.1 | 1.04 | 52.2 | 7.9 | 14.4 | 5.7 |
| E15 | 51.9 | 1 | 52 | 11.4 | 4.2 | 5.7 |
| E16 | 43.4 | 1.18 | 51.1 | 19 | 6.8 | 4.3 |
| E17 | 47 | 1.1 | 51.9 | 8.1 | 5.9 | 4.9 |
| E18 | 46.5 | 1.12 | 52 | 6.2 | 6.7 | 4.9 |
| E19 | 40.8 | 1 | 40.6 | 8.7 | 17.4 | 5.9 |
| E20 | 38.8 | 0.95 | 37 | 11.8 | 13.1 | 5.9 |
| E21 | 45.4 | 0.82 | 37.4 | 7.2 | 18 | 5.9 |
| E22 | 35.7 | 1.05 | 37.4 | 7 | 18 | 4.3 |
| CE1 | 68.5 | 0.98 | 67.1 | 19 | 15.3 | 5.7 |
| CE2 | 56.4 | 0.92 | 52 | 17.1 | 13.3 | 5.7 |
| CE3 | 44.9 | 0.82 | 37 | 18.4 | 17.4 | 5.9 |

TABLE 8

| | a*T | b*T | a*Rext | b*Rext | a*Rint | b*Rint |
|---|---|---|---|---|---|---|
| E1 | −0.4 | 0.9 | −4 | −13.1 | −7.9 | −10 |
| E2 | −4 | −3.2 | −4.8 | −12.6 | −3.4 | −9.7 |
| E3 | −3.6 | −1.8 | −2 | −5.7 | −4 | −10 |
| E4 | −3.6 | −2.8 | −6 | −8.9 | 2 | −10 |
| E5 | −3.5 | −1.8 | −0.9 | −6.3 | −4 | −10 |
| E6 | −2.1 | −1.2 | −1.6 | −8.8 | 2 | −10 |
| E7 | −3.8 | −0.7 | −6 | −5.9 | −4 | −10 |
| E8 | −3.8 | −1.6 | −5.4 | −0.8 | 2 | −10 |
| E9 | −4 | −0.5 | −6 | −13 | −2.7 | −7.6 |
| E10 | −4 | −4 | −6 | −4.9 | 0.7 | −4.7 |
| E11 | −4 | 2 | −6 | −1.6 | −4 | −9.7 |
| E12 | −4 | 0.3 | −6 | −5.9 | −3.8 | −9.6 |
| E13 | −7 | −6.5 | −6 | −10.7 | −4 | −8.4 |
| E14 | −4.2 | −5.4 | −6 | −10.6 | −4 | −10.4 |
| E15 | −2.1 | −4 | −4.7 | −12.9 | 2 | −10 |
| E16 | −3.4 | −0.9 | −6 | −13 | −0.9 | −9 |
| E17 | −3.1 | −4 | −6 | −4.6 | −4 | −10 |
| E18 | −4 | −2 | −6 | −13 | −0.1 | −9.9 |
| E19 | −8.9 | −11.7 | −6.6 | −14.2 | −2.9 | −5.3 |
| E20 | −1.2 | −4.1 | −6 | 0 | −4 | −1.1 |
| E21 | −1.9 | −5.1 | −4.8 | −7.1 | 2.1 | −6.1 |
| E22 | −4.8 | −4.7 | 1 | −7.8 | 0.7 | −10 |
| CE1 | −1 | 0.6 | −2.4 | −7.8 | −0.7 | −4.4 |
| CE2 | −1.5 | −2.2 | −1.7 | −9.6 | 0.9 | 2 |
| CE3 | −1.6 | −4.4 | −0.5 | −7.3 | 1.9 | 10 |

Table 7 shows that the emissivity levels of the examples are lower than, if not equivalent to, those of the counter-examples.

The light transmission, TL, and solar factor, g, values are shown in FIG. 5 for examples E1 to E12 (solid circles), E13 to E18 (solid squares), and E19 to E22 (solid triangles), and the respective counter-examples CE1 (empty circle), CE2 (empty square) and CE3 (empty triangle). This graph also shows the selectivity thresholds, s=0.8, s=1.0 and s=1.2 as guides for the eyes.

FIG. 5 shows that, for equivalent light transmission, the examples have higher selectivity values than the respective counter-examples. The gain in selectivity can be as much as 0.3 or even 0.4 points.

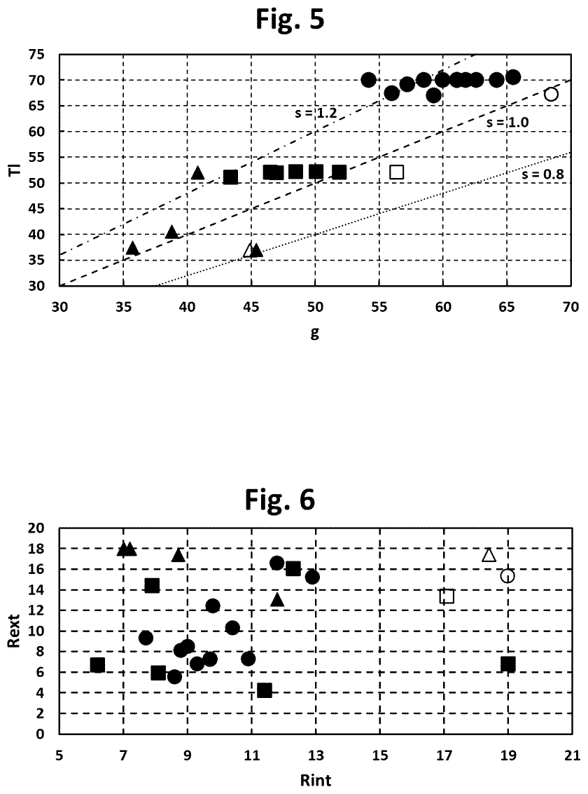

The external and internal reflection values are shown in FIG. 6 for examples E1 to E12 (solid circles), E13 to E18 (solid squares), and E19 to E22 (solid triangles), and the respective counter-examples CE1 (empty circle), CE2 (empty square) and CE3 (empty triangle).

FIG. 6 shows that the examples according to the invention have reflection levels on the internal face and on the external face less than, or otherwise equivalent to, those of the counter-examples for comparable light transmission values. In other words, the invention also makes it possible to reduce light reflection, in particularly on the internal face, while preserving the same level of light transmission.

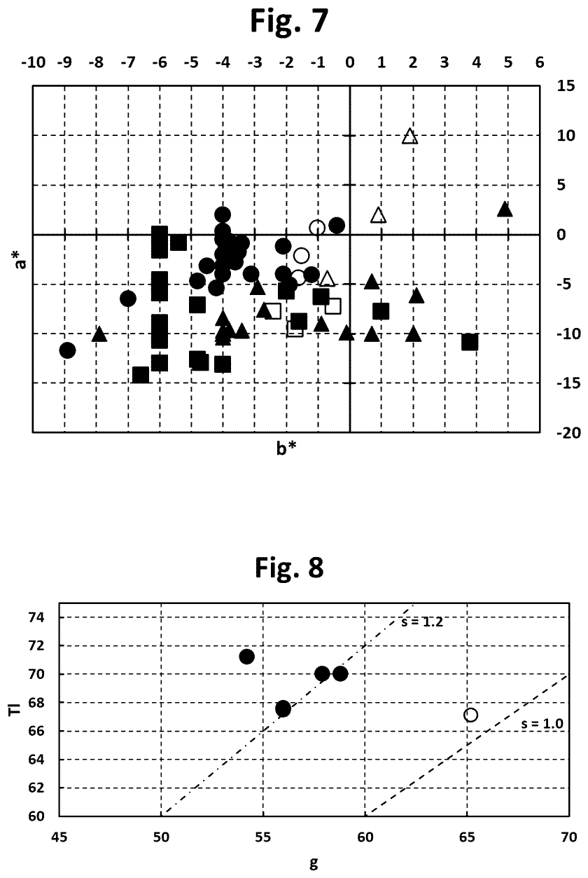

The values of the color parameters a*, b* are shown in FIG. 7 for examples E1 to E22 (shown solid) and counter-examples CE1 to CE3 (shown empty). The color parameters in transmission a*T, b*T are represented by circles, the parameters in reflection on the exterior face a*Rext, b*Rext are represented by triangles, and the parameters in reflection on the interior face a*Rint, b*Rint are represented by squares.

In transmission, the examples according to the invention have a lower color parameter b* than the counter-examples.

In external face reflection, the examples according to the invention have a lower color parameter b*Rext than the counter-examples.

In internal face reflection, the examples according to the invention have lower color parameters a*Rint and b*Rint than the counter-examples.

The stacks 1001 of examples E1, E2, E3, E9 and E11 of counter-example CE1 have also been used to form laminated glazings, labeled VFE1, VFE2, VFE3, VFE9, VFE11 and VFCE1, respectively.

Functional coatings 1001 were deposited under the same conditions as above on sheets 1000 of 4 mm thick soda-lime-silica mineral glass. Just after deposition, the functional coatings were subjected to a heat treatment at 650° C. for 10 min.

Once deposition and heat treatment have been completed, each of the glass sheets 1000 with a functional coating 1001 is laminated with a lamination interlayer 2001 of 0.38 mm thick PVB and a second glass sheet 2002 of 4 mm thick soda-lime-silica mineral glass to form a laminated glazing as shown in FIG. 4.

The solar factor, g, the selectivity, s, the light transmission, TI, the light reflection on the interior face, Rint, and on the exterior face, Rext, as well as the color in transmission, on the interior face and on the exterior face, were measured for each substrate of examples VFE1, VFE2, VFE3, VFE9, VFE11 and of counter-examples VFCE1 assembled in a laminated glazing.

The expression “color”, used to describe a laminated glazing provided with a stack, is understood to mean the color as defined in the L*a*b* CIE 1976 chromatic space according to standard ISO 11664, in particular with a D65 illuminant and a visual field of 2° or 10° for the reference observer. It is measured in accordance with said standard.

The light transmission in the visible spectrum, TL, the solar factor, g, and the selectivity, s, and the internal reflection, Rint, and the external reflection, Rext, in the visible spectrum are defined, measured and calculated in conformity with the standards EN 410, ISO 9050 and/or ISO 10292.

The thermal transmission factor, Ug, is defined, measured and calculated in accordance with standard EN 673.

Measurements of solar factor, selectivity, light transmission, internal reflection, external reflection and emissivity are grouped together in Table 9. Measurements of color parameters a* and b*, in transmission (a*T, b*T), external reflection (a*Rext, b*Rext) and internal reflection (a*Rint, b*Rint) are grouped together in Table 10.

TABLE 9

| | g | s | Tl | Rint | Rext | Ug |
|---|---|---|---|---|---|---|
| VFE1 | 56 | 1.21 | 67.5 | 7.7 | 7.3 | 5.6 |
| VFE2 | 54.2 | 1.31 | 71.2 | 11.8 | 11.7 | 5.6 |
| VFE3 | 56 | 1.21 | 67.6 | 7.7 | 7.4 | 5.6 |
| VFE9 | 58.8 | 1.19 | 70 | 10.2 | 9.9 | 5.6 |
| VFE11 | 57.9 | 1.21 | 70 | 8.7 | 8.6 | 5.6 |
| VFCE1 | 65.2 | 1.03 | 67.1 | 13 | 8.4 | 5.6 |

TABLE 10

| | a*T | b*T | a*Rext | b*Rext | a*Rint | b*Rint |
|---|---|---|---|---|---|---|
| VFE1 | −4 | −3.9 | −6 | −6 | −3.4 | −7.4 |
| VFE2 | −4.4 | −3.6 | −4.6 | −10.1 | −4.7 | −10 |
| VFE3 | −4 | −3.8 | −6 | −6.1 | −3.3 | −7.5 |
| VFE9 | −4 | 1.3 | −6 | −6.1 | −4 | −6.7 |
| VFE11 | −4 | −0.6 | −6 | −5.3 | −4 | −3.5 |
| VFCE1 | −1.7 | 0 | −1 | −4.9 | −0.6 | −2.4 |

Table 9 shows that the emissivity levels of the examples are lower than, if not equivalent to, those of the counter-examples.

The light transmission, TL, and solar factor, g, values are shown in FIG. 8 for examples VFE1, VFE2, VFE3, VFE9, VFE11 (solid circles) and counter-example VFCE1 (empty circle). This graph also shows the selectivity thresholds, s=1.0 and s=1.2 as guides for the eyes.

FIG. 8 shows that, for equivalent light transmission, the examples have higher selectivity values than the respective counter-examples. The gain in selectivity can be as much as 0.2 points.

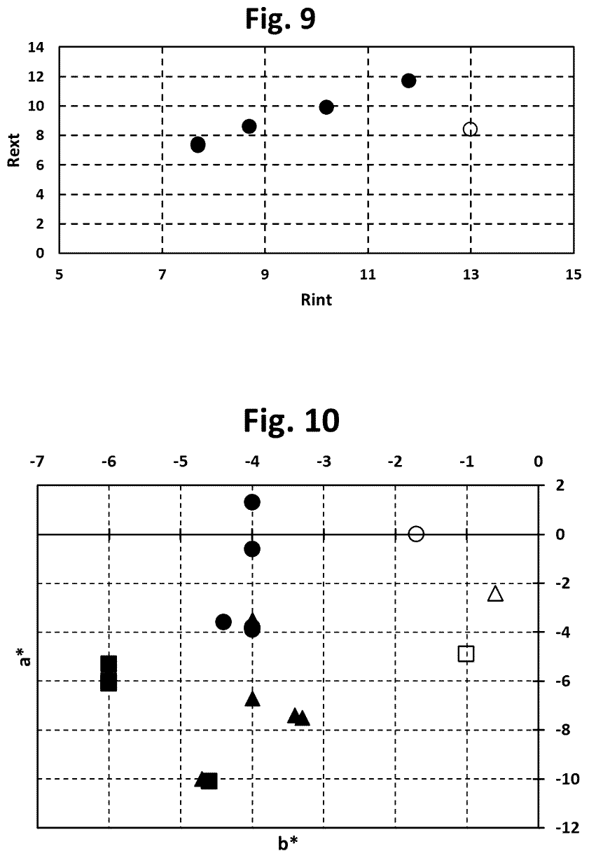

The external and internal reflection values are shown in FIG. 9 for VFE1, VFE2, VFE3, VFE9, VFE11 (solid circles) and counter-example VFCE1 (empty circle).

FIG. 9 shows that the examples according to the invention have reflection levels on the internal face and on the external face less than, or otherwise equivalent to, those of the counter-examples for comparable light transmission values. In other words, the invention also makes it possible to reduce light reflection, in particularly on the internal face, while preserving the same level of light transmission.

The values of the color parameters at, b* are shown in FIG. 10 for examples VFE1, VFE2, VFE3, VFE9, VFE11 (shown solid) and counter-example VFCE1 (shown empty). The color parameters in transmission a*T, b*T are represented by circles, the parameters in reflection on the exterior face a*Rext, b*Rext are represented by triangles, and the parameters in reflection on the interior face a*Rint, b*Rint are represented by squares.

In transmission, the examples according to the invention have a lower color parameter b* than the counter-example.

In external face reflection, the examples according to the invention have a lower color parameter b*Rext than the counter-example.

In internal face reflection, the examples according to the invention have lower color parameters a*Rint and b*Rint than the counter-example.

1. A transparent substrate provided on one of its main surfaces with a stack of thin layers, said stack of layers consisting of the following layers starting from the substrate:
a first dielectric module of one or more thin layers;
an absorbent layer of tungsten oxide;
a second dielectric module of one or more thin layers;
wherein the tungsten oxide comprises at least one doping element selected from the chemical elements of group 1 according to the IUPAC nomenclature.

2. The substrate according to claim 1, wherein the absorbent layer of tungsten oxide layer comprises the doping element or several doping elements in proportions such that a molar ratio of said element to tungsten or a sum of molar ratios of each element to tungsten is between 0.01 and 1.

3. The substrate according to claim 1, wherein the absorbent layer of tungsten oxide comprises at least one doping element selected from hydrogen, lithium, sodium, potassium and cesium.

4. The substrate according to claim 3, wherein the absorbent tungsten oxide layer comprises cesium as a doping element, and a molar ratio of cesium to tungsten is between 0.01 and 1, preferably between 0.05 and 0.4.

5. The substrate according to claim 1, wherein a thickness of the absorbent layer of tungsten oxide is between 6 and 450 nm.

6. The substrate according to claim 1, wherein the first dielectric module and/or the second dielectric module consist of one or more nitride-based layers.

7. The substrate according to claim 6, wherein the nitride-based layer(s) of the first dielectric module and/or the second dielectric module are chosen from aluminum nitride, silicon nitride, titanium nitride, niobium nitride, silicon zirconium nitride, silicon nitride doped with aluminum, zirconium and/or boron.

8. A single or double glazing comprising a transparent substrate according to claim 1.

9. A laminated glass comprising a first transparent substrate according to claim 1, a lamination interlayer and a second transparent substrate, wherein the first transparent substrate and the second transparent substrates are in adhesive contact with the lamination interlayer and the stack of thin layers of the first transparent substrate is in contact with the lamination interlayer.

10. A method for manufacturing a transparent substrate according to claim 1, comprising depositing the absorbent layer of tungsten oxide by a magnetron sputtering method using a tungsten oxide target doped using a chemical element chosen from the chemical elements of group 1 according to the IUPAC nomenclature.

11. The manufacturing method according to claim 10, wherein the absorbent layer of tungsten oxide is deposited at a substrate temperature of less than 100° C.

12. The manufacturing method according to claim 10, wherein the absorbent layer based on tungsten oxide is deposited in a deposition atmosphere composed of 60 to 100% argon and 0 to 40% dioxygen.

13. The manufacturing method according to claim 10, wherein the absorbent layer of tungsten oxide is deposited at a pressure of between 1 and 15 mTorr.

14. The substrate according to claim 2, wherein the molar ratio of said element to tungsten or the sum of the molar ratios of each element to tungsten is between 0.01 and 0.6.

15. The substrate according to claim 14, wherein the molar ratio of said element to tungsten or the sum of the molar ratios of each element to tungsten is between 0.03 and 0.3.

16. The substrate according to claim 4, wherein the molar ratio of cesium to tungsten is between 0.05 and 0.4.

17. The substrate according to claim 5, wherein the thickness of the absorbent layer of tungsten oxide is between 20 and 250 nm.

18. The manufacturing method according to claim 12, wherein the substrate temperature is between 2° and 60° C.

19. The manufacturing method according to claim 12, wherein the deposition atmosphere is composed of 70 to 85% argon and 15 to 30% dioxygen.

20. The manufacturing method according to claim 13, wherein the pressure is between 3 and 10 mTorr.
